(19) United States
(12) Patent Application Publication
(10) Pub. No.: US 2024/0405181 A1
(43) Pub. Date: Dec. 5, 2024

(54) SEMICONDUCTOR DEVICE ARRANGEMENT AND METHOD OF MANUFACTURING THE SAME

(71) Applicant: EPISTAR CORPORATION, Hsinchu (TW)

(72) Inventors: Min-Hsun HSIEH, Hsinchu (TW); Shih-An LIAO, Hsinchu City (TW); Wei-Yu CHEN, Hsinchu (TW); Li-Shen TANG, Hsinchu (TW); Kun-Wei KAO, Hsinchu (TW); Jia-Xing CHUNG, Hsinchu City (TW); Wei-Shan HU, Hsinchu City (TW); Ching-Tai CHENG, Hsinchu (TW); Chang-Tai HSIAO, Hsinchu (TW); Yih-Hua RENN, Hsinchu (TW); Chun-Yen WU, Hsinchu (TW)

(21) Appl. No.: 18/733,304

(22) Filed: Jun. 4, 2024

Related U.S. Application Data
(60) Provisional application No. 63/471,082, filed on Jun. 5, 2023.

(51) Int. Cl. H01L 33/62; H01L 25/075; H01L 33/40

(52) U.S. Cl. CPC H01L 33/62; H01L 25/0753; H01L 33/40; H01L 2933/0066

(57) ABSTRACT

An embodiment of the present disclosure provides a semiconductor device arrangement. This arrangement includes a substrate, an adhesive structure, and a first semiconductor device. The substrate includes an upper surface. The adhesive structure is located on the upper surface and includes a first concave region. The first semiconductor device includes a lower surface facing toward the adhesive structure and a conductive bump located under the lower surface and in the first concave region. The conductive bump includes a first portion and a second portion. Wherein the lower surface does not contact the adhesive structure, the first portion contacts the first concave region, and the second portion does not contact the first concave region.

This application claims priority to the benefit of U.S. Provisional Patent Application No. 63/471,082 filed on Jun. 5, 2023 and the entire content of which is hereby incorporated by reference herein in its entirety.

### TECHNICAL FIELD

The present disclosure relates to a semiconductor device arrangement, and more particularly, to a semiconductor device arrangement with conductive bumps and a method of manufacturing the same.

### DESCRIPTION OF BACKGROUND ART

A light-emitting diode (LED) is an optoelectronic semiconductor device that is suitable for diverse lighting and display applications because it has good characteristics, such as low power consumption, low heat generation, long operation life, shock tolerance, a compact size, and swift response.

As the continuous advancements in LED technology, the brightness of an LED die is increasing continuously, and the size of LED die is also gradually being reduced to, e.g., less than 100 μm, 50 μm, or 30 μm. The use of LED dies is no longer limited to general lighting applications or as a backlight source in LCD monitors. To use LED dies directly as the pixels of an LED display could become a trend in next-generation displays.

An LED display is composed of millions or even tens of millions of LED chips. Precisely placing such a large number of LED dies on a display panel requires fast and reliable die transfer technology.

### SUMMARY OF THE APPLICATION

According to one embodiment of the present disclosure, a semiconductor device arrangement is provided. This arrangement includes a substrate, an adhesive structure, and a first semiconductor device. The substrate includes an upper surface. The adhesive structure is located on the upper surface and includes a first concave region. The first semiconductor device includes a lower surface facing toward the adhesive structure and a conductive bump located under the lower surface and in the first concave region. The conductive bump includes a first portion and a second portion. Wherein the lower surface does not contact the adhesive structure, the first portion contacts the first concave region, and the second portion does not contact the first concave region.

According to another embodiment of the present disclosure, a method of manufacturing a semiconductor device arrangement is provided. This method includes providing a substrate, an adhesive structure, a first semiconductor device, and a second semiconductor device. Wherein, the substrate includes an upper surface; the adhesive structure is located on the upper surface; and the first semiconductor device and the second semiconductor device are located on the adhesive structure. Providing an energy to the first semiconductor device such that a contact area between the first semiconductor device and the adhesive structure is reduced; providing a transferring structure to simultaneously contact the first semiconductor device and the second semiconductor device; and removing the transferring structure to transfer the first semiconductor device to the transferring structure.

### BRIEF DESCRIPTION OF THE DRAWINGS

The embodiments of the present disclosure may be more fully understood by reading the subsequent detailed description and examples with references made to the accompanying drawings. In addition, for clarity, the features in the drawings may not be drawn to actual scale, so some features in some drawings may be deliberately enlarged or reduced in size, wherein:

FIG. 1A illustrates a top view of a semiconductor device arrangement in accordance with one embodiment of the present disclosure.

FIG. 1B illustrates is a cross-sectional view taken along line A-A′ of FIG. 1A.

FIG. 1C illustrates a top view of a semiconductor device arrangement in accordance with another embodiment of the present disclosure.

FIG. 1D illustrates is a cross-sectional view taken along line A-A′ of FIG. 1C.

FIG. 1E illustrates a cross-sectional view of a semiconductor device arrangement in accordance with another embodiment of the present disclosure.

FIG. 2A illustrates a stereogram of a semiconductor device arrangement in accordance with one embodiment of the present disclosure.

FIG. 2B illustrates is a cross-sectional view taken along line B-B′ of FIG. 2A.

FIG. 2C illustrates a cross-sectional view of a semiconductor device arrangement in accordance with another embodiment of the present disclosure.

FIG. 2D illustrates a stereogram of a semiconductor device arrangement in accordance with another embodiment of the present disclosure.

FIG. 2E illustrates is a cross-sectional view taken along line B-B′ of FIG. 2D.

FIG. 3A illustrates a top view of a semiconductor device arrangement in accordance with one embodiment of the present disclosure.

FIG. 3B illustrates is a cross-sectional view taken along line C-C′ of FIG. 3A.

FIG. 3C illustrates is a cross-sectional view taken along line D-D′ of FIG. 3A.

FIG. 4A illustrates a cross-sectional view of a semiconductor device arrangement in accordance with another embodiment of the present disclosure.

FIG. 4B illustrates a cross-sectional view of the semiconductor device arrangement of FIG. 4A after removing one semiconductor device.

FIG. 4C illustrates a top view of the semiconductor device arrangement of FIG. 4A after removing one semiconductor device.

FIG. 4D illustrates a cross-sectional view of a semiconductor device arrangement in accordance with another embodiment of the present disclosure.

FIG. 4E illustrates a cross-sectional view of a semiconductor device arrangement in accordance with another embodiment of the present disclosure.

FIGS. 5A-5D are schematic views of various stages for transferring semiconductor devices in accordance with an embodiment of the present disclosure.

FIGS. 6A-6C are schematic views of various stages for transferring semiconductor devices in accordance with another embodiment of the present disclosure.

FIGS. 7A-7D are schematic views of various stages in a method of manufacturing semiconductor devices in accordance with an embodiment of the present disclosure.

FIGS. 8A-8D are schematic views of various stages in a method of manufacturing semiconductor devices in accordance with another embodiment of the present disclosure.

FIG. 9A illustrates a stereogram of a semiconductor device in accordance with one embodiment of the present disclosure.

FIG. 9B illustrates a cross-sectional view taken along line B-B′ of FIG. 9A.

FIGS. 10A-10E are schematic views of various stages for transferring semiconductor devices in accordance with another embodiment of the present disclosure.

FIG. 11A illustrates an enlarged view of a semiconductor unit in region P of FIG. 10C before being irradiated with a laser energy.

FIG. 11B illustrates an enlarged view of a semiconductor unit in region P of FIG. 10C after being irradiated with a laser energy.

FIGS. 12A-12D are schematic views of various stages for transferring semiconductor devices in accordance with another embodiment of the present disclosure.

FIGS. 13A-13C are schematic views of various stages for transferring semiconductor devices in accordance with another embodiment of the present disclosure.

FIG. 14 illustrates a cross-sectional view of a semiconductor device arrangement in accordance with another embodiment of the present disclosure.

### DETAILED DESCRIPTION OF THE APPLICATION

The semiconductor device arrangements and manufacturing methods thereof in accordance with the embodiments of the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. The embodiments are used merely for the purpose of illustration. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments.

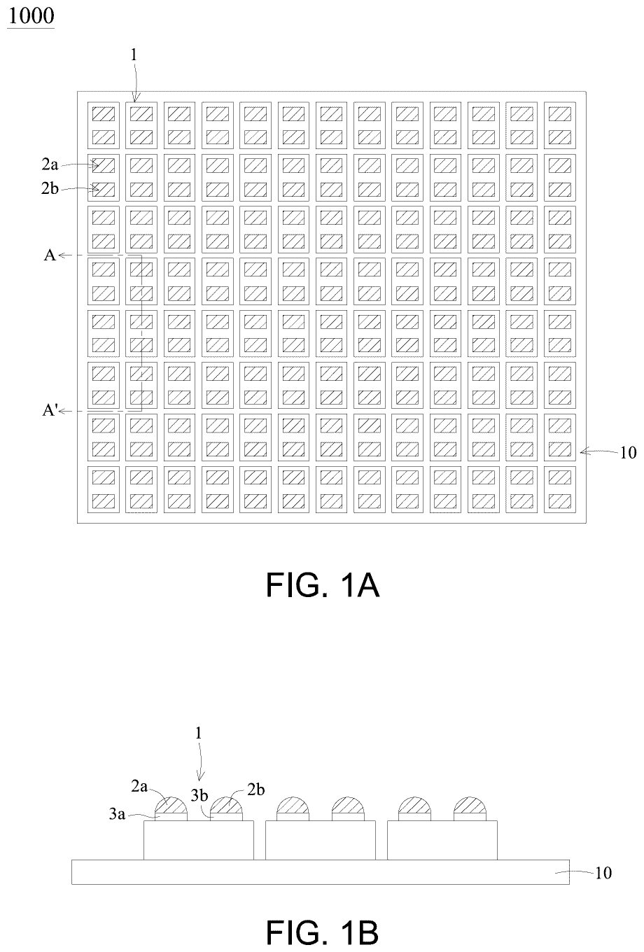

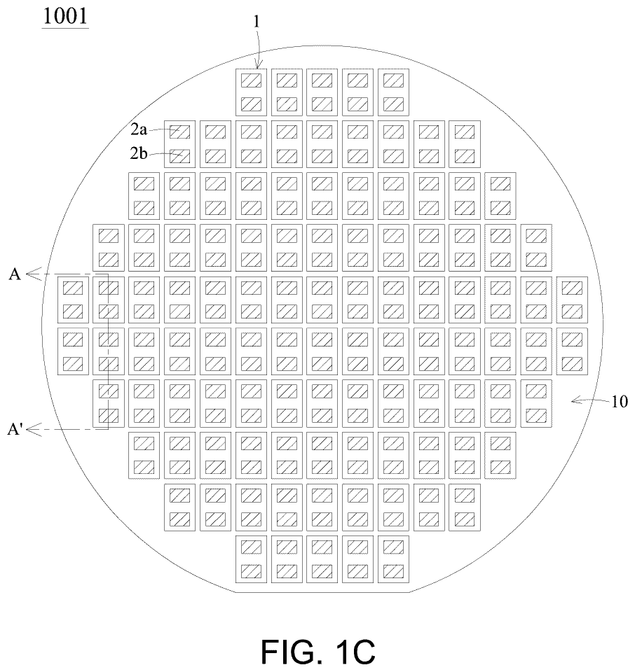

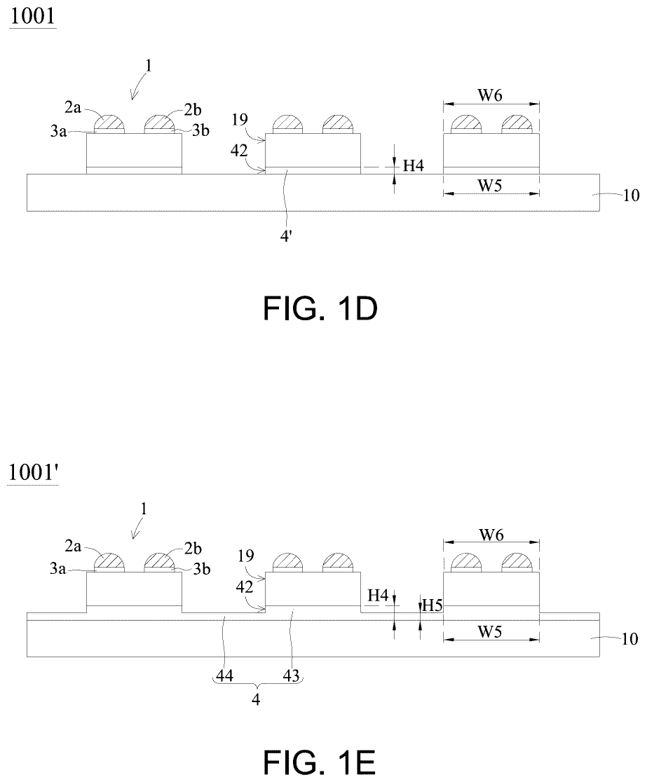

FIG. 1A is a top view of a semiconductor device arrangement 1000 in accordance with an embodiment of the present disclosure. The semiconductor device arrangement 1000 includes a plurality of semiconductor devices 1 arranged in an array on a substrate 10. The semiconductor device 1 may be a light-emitting diode (LED), laser diode (LD), or a transistor. The semiconductor device arrangement 1000 may be composed of a single type or various types of semiconductor device 1. The substrate 10 can be a growth substrate of the semiconductor device or can be a temporary carrier (non-growth substrate) to support the semiconductor device. The material of the substrate 10 includes but is not limited to: germanium (Ge), gallium arsenide (GaAs), indium phosphide (InP), sapphire, silicon carbide (SiC), silicon (Si), lithium aluminate (LiAlO₂), zinc oxide (ZnO), gallium nitride (GaN), aluminum nitride (AlN), metal, glass, thermal release tape, UV release tape, chemical release tape, heat resistant tape, blue tape, or tapes with dielectric release layer. Each of the semiconductor devices 1 has a pair of conductive bumps 2a, 2b for electrically or physically connecting to the external circuit (e.g., circuit board, backplane) on the side away from the substrate 10. The projected shape of the conductive bump is substantially rectangular in the top view, as shown in FIG. 1A.

FIG. 1B is a cross-sectional view taken along line A-A′ of FIG. 1A. The semiconductor device 1 has a pair of electrodes 3a, 3b on the side away from the substrate 10. The conductive bumps 2a, 2b are disposed on the electrode 3a, 3b, respectively. The upper surfaces of the conductive bumps 2a, 2b are of arc shape and not parallel to the upper surfaces of the electrodes 3a, 3b.

In one embodiment, the material of the conductive bumps 2a, 2b is different from the material of the electrodes 3a, 3b. The material of the electrodes 3a, 3b includes gold (Au), silver (Ag), copper (Cu), chromium (Cr), aluminum (Al), platinum (Pt), nickel (Ni), titanium (Ti), alloys thereof, or combinations of the stacking layers thereof. The material of the conductive bumps 2a, 2b may include a low melting point metal or a low liquidus melting point alloy, whose melting point or liquidus temperature is lower than 210° C., such as bismuth (Bi), tin (Sn), indium (In), or alloys thereof. In an embodiment, the melting point of the low melting point metal or the liquidus temperature of the low liquidus melting point alloy is lower than 170° C. The material of the low liquidus melting point alloy may be tin-indium alloy or tin-bismuth alloy.

FIG. 1C is a top view of a semiconductor device arrangement 1001 in accordance with another embodiment of the present disclosure. The semiconductor device arrangement 1001 includes a plurality of semiconductor devices 1 arranged in a predetermined pattern on the substrate 10. The substrate 10 has a substantially circular shape. For the material of the substrate 10, reference can be made to the aforementioned relevant paragraphs. FIG. 1D is a cross-sectional view taken along line A-A′ of FIG. 1C. A sub-adhesive structure 4 is between each semiconductor device 1 and the substrate 10. Each of the plurality of semiconductor devices 1 is temporally fixed on the substrate 10 by the sub-adhesive structure 4. Each of the plurality of semiconductor devices 1 has a pair of the electrodes 3a, 3b on the side away from the substrate 10. The conductive bumps 2a, 2b are disposed on the electrodes 3a, 3b, respectively. The upper surfaces of the conductive bumps 2a, 2b are of arc shape from the lateral view and not completely parallel to the upper surfaces of the electrodes 3a, 3b. The sub-adhesive structure 4 may include polymer, such as polyimide (PI), acrylic resin, epoxide resin (EPO), polybenzoxazole (PBO), polysiloxane, cyclic olefin polymer (COP), or benzocyclobutane (BCB). For the material of the conductive bumps 2a, 2b and the material of the electrodes 3a, 3b, reference can be made to the aforementioned relevant paragraphs.

As shown in FIG. 1D, for each semiconductor device 1, an outer side 42 of the sub-adhesive structure 4 is substantially coplanar with an outermost side 19 of the semiconductor device 1. The sub-adhesive structure 4 has a thickness H4, which is about 2-3 μm or 1-10 μm. In other words, the sub-adhesive structure 4 has a maximum width W5, the semiconductor device 1 has a maximum width W6, and W5 is substantially the same as W6. In another embodiment, for each of the semiconductor devices 1, the outer side 42 is not coplanar with the outermost side 19 of the semiconductor device 1, and the sub-adhesive structure 4 can be retracted or protruded relative to the outermost side 19 of the semiconductor device 1. That is, the maximum width W5 can be less than or more than the maximum width W6.

FIG. 1E is a cross-sectional view of the semiconductor device arrangement 1003 in accordance with another embodiment of the present disclosure. The semiconductor device arrangement 1003 includes a plurality of semiconductor devices 1 arranged in a predetermined pattern on a substrate 10. An adhesive structure 4′ is between the plurality of semiconductor devices 1 and the substrate 10. The plurality of semiconductor devices 1 is temporarily fixed on the substrate 10 by the adhesive structure 4′. Each semiconductor device 1 has a pair of the electrodes 3a, 3b on the side away from the substrate 10. The conductive bumps 2a, 2b are disposed on the electrodes 3a, 3b, respectively.

As shown in FIG. 1E, the adhesive structure 4′ has mesa portions 43 and continuous portions 44. The continuous portions 44 are uninterrupted and continuously disposed on the substrate 10 across the areas below the plurality of semiconductor devices 1 and between two adjacent semiconductor devices 1. Each of the mesa portions 43 is between each of the semiconductor devices 1 and the continuous portions 44, protruding from the continuous portion 44 and corresponding to one of the plurality of semiconductor devices 1. For each of the plurality of semiconductor devices 1, the outer side 42 of the mesa portion 43 is coplanar with or near the outermost side 19 of the semiconductor device 1. The adhesive portion 4 has a thickness H4, which is about 2-3 μm. The continuous portion 44 has a thickness H5, which is more than 0 μm and less than 1 μm. In other words, the mesa portion 43 has a maximum width W5 and the semiconductor device 1 has a maximum width W6, and the maximum width W5 is substantially equal to the maximum width W6. In another embodiment, for each semiconductor device 1, the outer side 42 is not coplanar with the outermost side 19 of the semiconductor device 1, and the mesa portion 43 can be retracted or protruded relatively to the outermost side 19 of the semiconductor device 1. That is, the maximum width W5 may be less than or more than the maximum width W6.

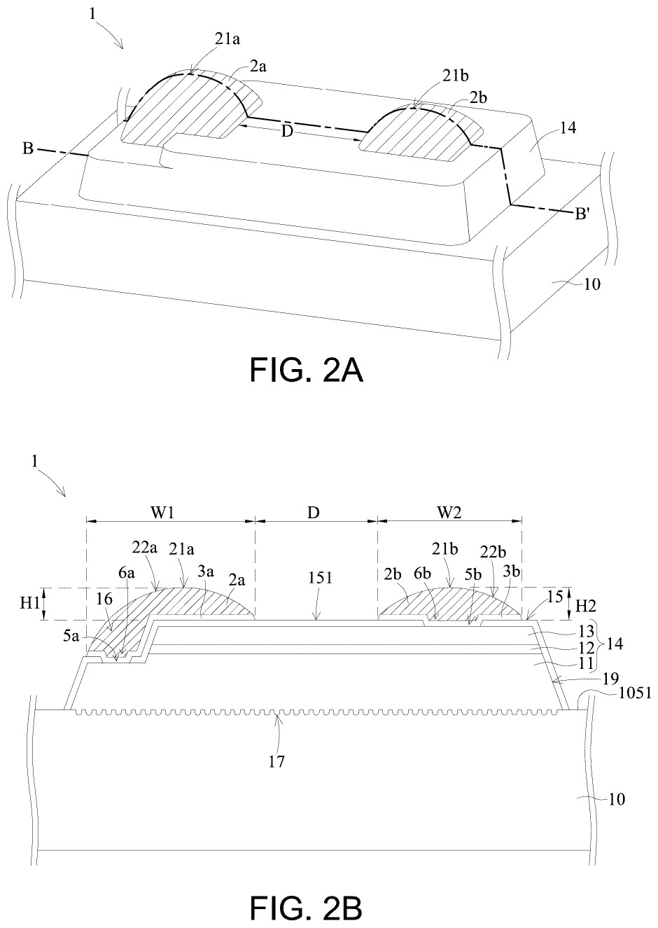

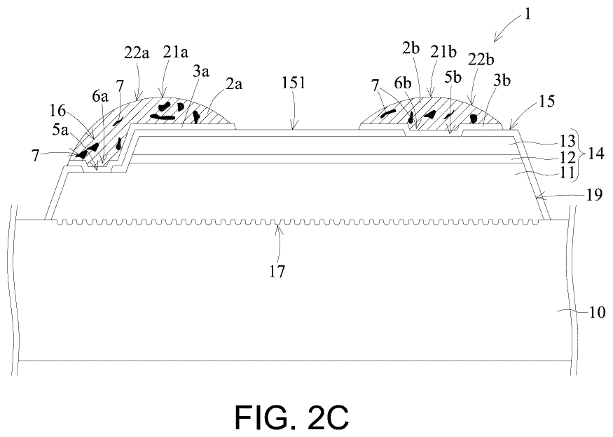

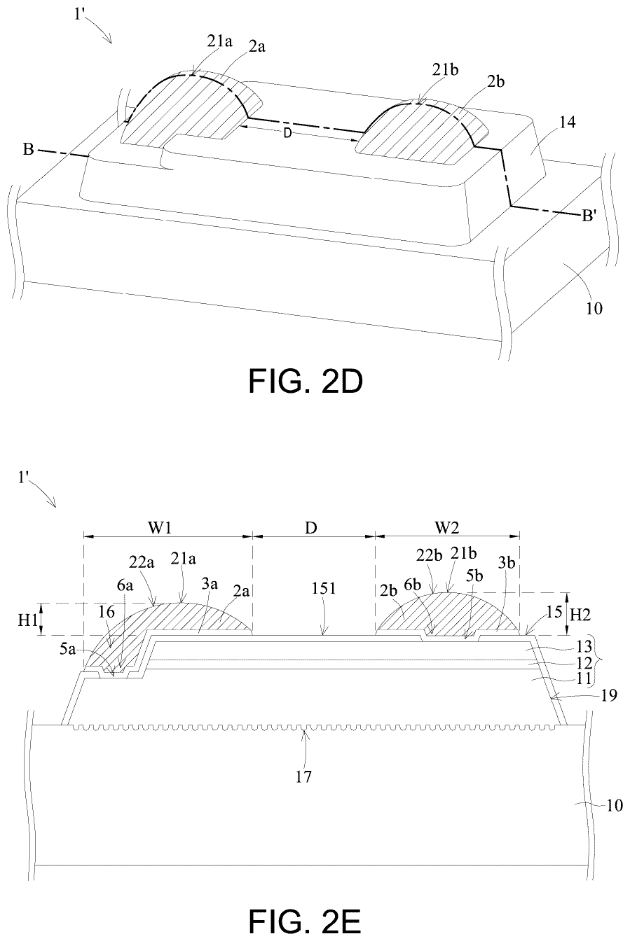

FIG. 2A is a three-dimensional view of a semiconductor device 1 on a substrate 10 in accordance with an embodiment of the present disclosure. The maximum side length of the semiconductor device 1 is not more than 100 μm or 50 μm. For example, the maximum side length of the semiconductor device is about 40 μm and the width thereof is about 20 μm. The conductive bump 2a and the conductive bump 2b have different polarities (positive, negative), and the minimal horizontal distance D therebetween is less than 40 μm. For example, the maximum side length of the semiconductor device 1 is about 40 μm and the distance D thereof is about 15 μm. The conductive bumps 2a, 2b cover the electrodes thereunder (not shown) completely and have convex arc shapes and tops 21a, 21b. Referring to FIG. 2A, the tops 21a, 21b are located approximately at the geometric center of the conductive bumps 2a, 2b and/or the electrodes.

FIG. 2B is a cross-sectional view of a semiconductor device 1 taken along line B-B′ of FIG. 2A. The semiconductor device 1 is placed on the substrate 10, and has a semiconductor stack 14, a protective layer 15, a first electrode 3a, a second electrode 3b, a first conductive bump 2a, and a second conductive bump 2b. The outermost side 19 of the semiconductor stack 14 is an inclined plane, which is not perpendicular to an upper surface 1051 of the substrate 10. In one embodiment, the semiconductor device 1 is an LED die, and the semiconductor stack 14 includes a first semiconductor layer 11, an active layer 12, and a second semiconductor layer 13. The first semiconductor layer 11 and the second semiconductor layer 13 can respectively provide electrons and holes so that the electrons and holes can recombine in the active layer 12 to emit light. The first semiconductor layer 11, the active layer 12 and the second semiconductor layer 13 may include III-V semiconductor material, such as AlₓIn_{y}Ga_{(1-x-y)}N or AlₓIn_{y}Ga_{(1-x-y)}P, wherein 0≤x, y≤1; (x+y)≤1. Depending on the material of the active layer 12, the LED die can emit a red light with a peak wavelength in a range of 610 nm and 650 nm, a green light with a peak wavelength in a range of 530 nm and 570 nm, a cyan light with a peak wavelength in a range of 500 nm and 485 nm, a blue light with a peak between 450 nm and 485 nm, a violet light with a peak wavelength in a range of 400 nm and 450 nm, or an ultraviolet light with a peak wavelength in a range of 280 nm and 400 nm. The maximum thickness of the semiconductor stack 14 is about equal to or less than 10 μm. In an embodiment, the lower surface 17 of the first semiconductor layer 11 is a rough surface and in contact with the substrate 10. In other words, the upper surface of the substrate 10 is in contact with the lower surface 17 of the first semiconductor layer 11. In another embodiment, the lower surface 17 of the first semiconductor layer 11 is a substantially flat surface (not shown). In another embodiment, the substrate 10 is a growth substrate for epitaxial growth of the semiconductor stack 14 and can be a patterned sapphire substrate (PSS) so the upper surface of the substrate 10 facing the semiconductor stack 14 is a rough surface (not shown). In an embodiment, the semiconductor device 1 includes a carrier (not shown) under the semiconductor stack 14 to support the semiconductor stack 14, and the carrier may be an epitaxial growth substrate of the semiconductor stack 14 or not an epitaxial growth substrate. For the material of the carrier, reference can be made to the aforementioned relevant paragraphs of the substrate 10, but the selection of materials should conform to the theoretical and practical feasibility.

As shown in FIG. 2B, the semiconductor stack 14 has a mesa 16 which is formed by removing a portion of the active layer 12 and the second semiconductor layer 13 to expose the first semiconductor layer 11. The protective layer 15 covers the upper surface of the second semiconductor layer 13, sidewalls of the first semiconductor layer 11, sidewalls of the active layer 12, sidewalls of the second semiconductor layer 13, and the upper surface of the first semiconductor layer 11 in the mesa 16. The protective layer 15 can contact the substrate 10. In another embodiment, the protective layer 15 is not in contact with the substrate 10. The protective layer 15 has a first opening 5a in the mesa 16 to expose portions of the first semiconductor stack 11. The protective layer 15 has a second opening 5b on the second semiconductor layer 13 to expose portions of the second semiconductor layer 13. The first electrode 3a is in the mesa 16 with a portion formed on the protective layer 15 and covering the protective layer 15. The first electrode 3a has a first recess 6a formed in the first opening 5a and is electrically connected to the first semiconductor layer 11. The first electrode 3a has a stepped shape in the area of the mesa 16. The second electrode 3b has a portion on the protective layer 15 outside the second opening 5b and a second recess 6b formed in the second opening 5b for being electrically connected to the second semiconductor layer 13.

The protective layer 15 may be a single-layer or multi-layer structure and has a property of electrical insulation. The material of the single-layer structure may include oxide, nitride, or polymer. The oxide may include aluminum oxide (Al₂O₃), silicon oxide (SiO₂), titanium oxide (TiO₂), tantalum pentoxide (Ta₂O₅), or aluminum oxide (AlOₓ). The nitride may include aluminum nitride (AlN) or silicon nitride (SiNₓ). The polymer may include polyimide or benzocyclobutane (BCB). The material of the multi-layer structure may include aluminum oxide (Al₂O₃), silicon oxide (SiO₂), titanium oxide (TiO₂), niobium pentoxide (Nb₂O₅), silicon nitride (SiNₓ), or combinations thereof. The multi-layer structure can also form a distributed Bragg reflector (DBR).

Referring to FIG. 2B, a first conductive bump 2a is formed over the first electrode 3a. The first conductive bump 2a may completely or partially fill the first recess 6a of the first electrode 3a, and the outermost surface 22a of the first conductive bump 2a has a macroscopically smooth and convex arc shape. The first conductive bump 2a has a top 21a, which is a region having farthest distance between the first conductive bump 2a and the substrate 10. As shown in FIG. 2B, the outermost surface 22a of the first conductive bump 2a does not contain any plane parallel to the lowest surface of the first conductive bump 2a, and is not parallel to the upper surface of the first electrode 3a, either. The lower surface 17 of the first semiconductor layer 11 is a rough surface, wherein the roughness of the outermost surface 22a of the first conductive bump 2a is less than the roughness of the lower surface 17 of the first semiconductor layer 11 and is less than the roughness of the upper surface of the first electrode 3a.

Referring to FIG. 2B, a second conductive bump 2b covers the second electrode 3b. The second conductive bump 2b may completely or partially fill the second recess 6b of the second electrode 3b, and the outermost surface 22b of the second conductive bump 2b has a macroscopically smooth and convex arc shape. The second conductive bump 2b has a top 21b, which is a region of the second conductive bump 2b farthest away from the substrate 10. As shown in the FIG. 2B, the outermost surface 22b of the second conductive bump 2b does not contain any plane parallel to the lowest surface of the second conductive bump 2b, and is not parallel to the upper surface of the second electrode 3b, either. The roughness of the outermost surface 22b of the second conductive bump 2a is less than the roughness of the lower surface 17 of the first semiconductor layer 11 and is less than the roughness of the upper surface of the second electrode 3b. In one embodiment, the top 21a of the first conductive bump 2a and the top 21b of the second conductive bump 2b are substantially in a same horizontal height, which is beneficial for the device 1 to be stably affixed on the substrate subsequently. However, in practice, there may be a certain degree of height difference under the tolerance of the fabrication process. Generally, the lowest surface of the first conductive bump 2a and the second conductive bump 2b are formed conformally on the first electrode 3a and the second electrode 3b, respectively, whereas their lowest points are not commonly in the same horizontal height. As shown in FIG. 2B, a first thickness H1 can be obtained by measuring the vertical distance from the top 21a of the first conductive bump 2a to the uppermost surface 151 of the protective layer 15. The first conductive bump 2a has a first (maximum) width W1, wherein the ratio H1/W1 is between 0.1-0.4, or between 0.1-0.25. A second thickness H2 can be obtained by measuring the vertical distance from the top 21b of the second conductive bump 2n to the uppermost surface 151 of the protective layer 15. The second conductive bump 2b has a second (maximum) width W2, wherein the ratio H2/W2 is between 0.1-0.4, or between 0.1-0.25. The ratios of H1/W1 and H2/W2 may be the same or different. The second thickness H2 of the second conductive bump 2b is between 4-6 μm.

If the first conductive bump 2a is more densely filled in the first recess 6a of the first electrode 3a and/or the second conductive bump 2b is more densely filled in the second recess 6b of the second electrode 3b, the reliability of the physical or electrical connection between the semiconductor device 1 and the circuit substrate (not shown) can be improved, and the probability of open circuit between the semiconductor device 1 and the circuit substrate can be reduced. Specifically, if the structure of the semiconductor device 1 is as shown in FIG. 2B but does not have the conductive bump 2a/2b, when the semiconductor device 1 is fixed to a circuit substrate by a solder, the solder between the first electrode 3a and the circuit substrate (not shown) may sometimes have holes near the first recess 6a, and the solder between the second electrode 3b and the circuit substrate (not shown) also may sometimes have holes near the second recess 6b. These holes may decrease the fixing strength between the semiconductor device 1 and the circuit substrate.

If a thermal treatment step is present during the formation of the conductive bump, under a specific combination of the selected materials of the conductive bump and the electrode, discretely distributed metal particles may be formed within the conductive bump after the thermal treatment step, as shown in FIG. 2C. FIG. 2C is a cross-sectional view of a semiconductor device 1 in accordance with another embodiment of the present disclosure. For the structure shown in FIG. 2C, reference can be made to FIG. 2B and the aforementioned relevant paragraphs. The first conductive bump 2a and the second conductive bump 2b have discretely distributed, irregularly sized and irregularly shaped particles 7 distributed therein. The material of the particles 7 is different from the material of the conductive bump 2a, 2b, but is partially the same as the material of the electrode 3a, 3b, such as gold, platinum, and alloy thereof. The shape of particles 7 may be bar shape, polygon, leaf shape, or teardrop shape.

FIGS. 2D-2E are schematic views of a semiconductor device 1′ in accordance with another embodiment of the present disclosure. The top 21a and top 21b are not in the same horizontal height. The top 21a is slightly lower than the top 21b. FIG. 2E is a cross-sectional view of a semiconductor device 1′ taken along line B-B′ of FIG. 2D. The conductive bump 2a is above the mesa 16. When the volume of the conductive bump 2a is similar to that of the conductive bump 2b, because a portion of the conductive bump 2a fills the mesa 16, the top 21a of the conductive bump 2a is slightly lower than the top 21b of the conductive bump 2b. In an embodiment, the first thickness H1 of the first conductive bump 2a is 0.4 to 1 μm less than the second thickness H2 of the second conductive bump 2b.

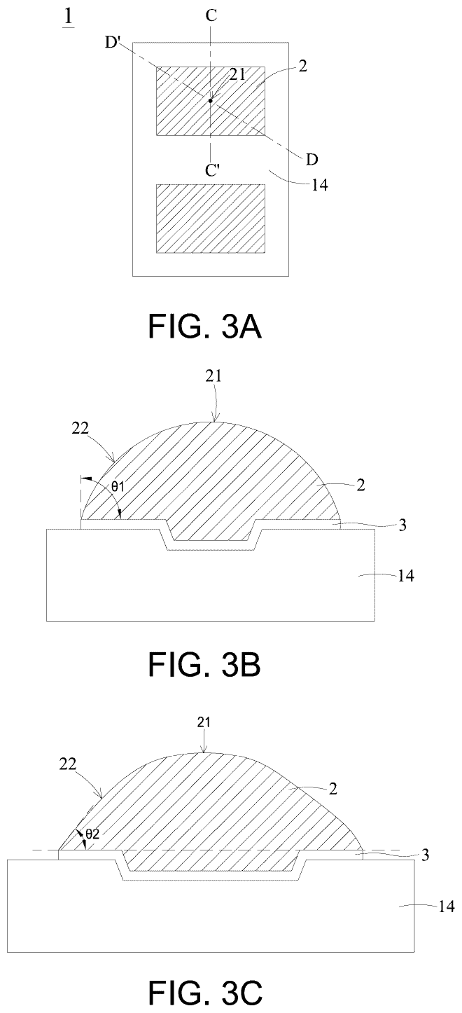

FIG. 3A is a top view of a semiconductor device 1 in accordance to an embodiment of the present disclosure. FIG. 3B is a cross-sectional view of a semiconductor device 1 taken along line C-C′ of FIG. 3A. FIG. 3C is a cross-sectional view of a semiconductor device 1 taken along line D-D′ of FIG. 3A. The semiconductor device 1 includes a semiconductor stack 14 and an electrode 3 as well as a conductive bump 2 on the semiconductor stack 14. The projected shape of the conductive bump 2 and the electrode 3 in FIG. 3A is substantially a rectangle. The outermost surface 22 of the conductive bump 2 has a macroscopically smooth and convex arc shape in the cross-sectional view. The outermost surface 22 is in contact with the upper surface of the electrode 3, and a tangent line of the outermost surface 22 at the contact point forms an angle θ1 with respect to the upper surface of the electrode 3. The angle θ1 is about 90° and can be in a range of 70°<θ1<90°. As shown in FIG. 3C, the outermost surface 22 is in contact with the upper surface of the electrode 3, and a tangent line of the outermost surface 22 at the contact point forms an angle θ2 with respect to the upper surface of the electrode 3. Angle θ2 is smaller than angle θ1 and can be in a range of 30°<θ2<70°. In other words, as shown in FIG. 3A, the cross-sectional shape of the conductive bump 2 in a direction that is parallel to the side length of the electrode is not equal to a cross-sectional shape of the conductive bump in a direction of a diagonal line D-D′ of the electrode 3.

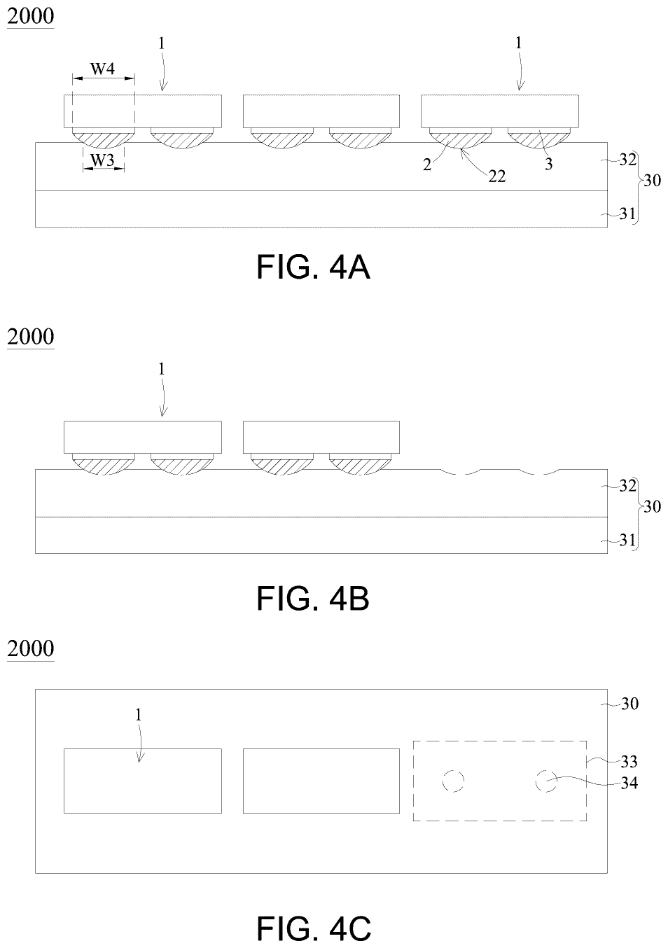

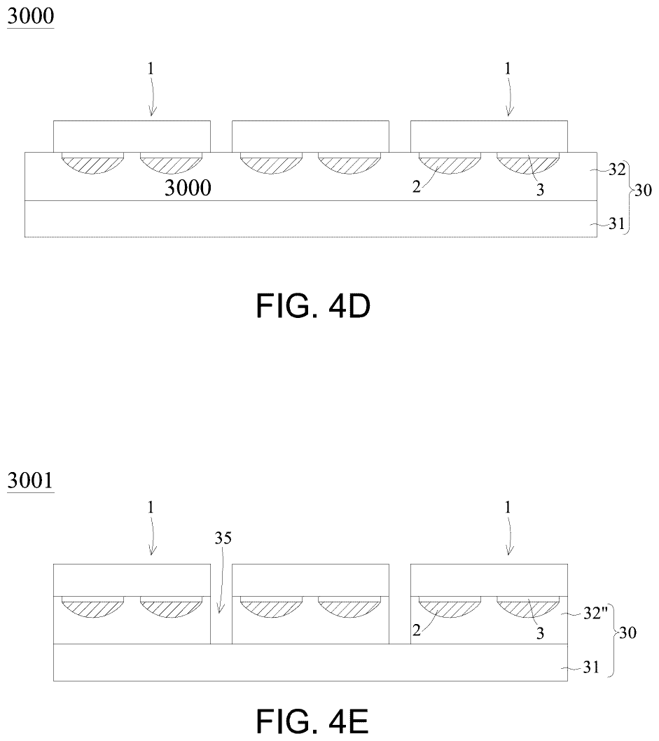

FIG. 4A shows a semiconductor device arrangement 2000 in accordance with an embodiment of the present disclosure. The semiconductor device arrangement 2000 includes a plurality of semiconductor devices 1 and a carrier 30. For simplicity, only three of the semiconductor devices 1 in one dimension are shown in FIG. 4A, but the semiconductor device arrangement 2000 may include m*n numbers of the semiconductor devices 1, wherein m, n are positive integers. The semiconductor devices 1 are disposed on the carrier 30 in a way that the conductive bumps 2 facing the carrier 30 (or called “flip-chip”). The carrier 30 may support and fix the semiconductor device 1. The carrier 30 includes a carrier plate 31 and an adhesive structure 32, wherein the material of the carrier plate 31 may be a light-transmitting material that can be transmitted by a light with a specific wavelength emitted by the LED or laser diode (LD), such as glass, sapphire, or polymer material. The adhesive structure 32 may include a thermal release tape, UV release tape, chemical release tape, heat resistant tape, blue tape, or tapes with dielectric release layer. In another embodiment, the adhesive structure 32 may also include a polymer, such as a polyimide and benzocyclobutane (BCB). When the semiconductor devices 1 are arranged on the carrier 30 in the form of “flip chip”, the smooth and convex outermost surfaces 22 of the conductive bumps 2 are in contact with the adhesive structure 32. As shown in the FIG. 4A, the conductive bumps 2 may have an embedded portion that is partially embedded in the adhesive structure 32. The embedded portion of each of the conductive bumps 2 has a maximum width W3 parallel to the surface of the adhesive structure 32, and the conductive bump 2 has a maximum width W4, wherein W4>W3. Besides, the outermost surface 22 of each of the conductive bumps 2 is smooth and arc-shaped, and, in a selected projection direction, the projected area of the portion of each of the conductive bumps 2 embedded in the adhesion layer (such as the area of the indentation 34 in FIG. 4C) is less than the area of the electrode 3 and has a lower adhesive force, which is beneficial for the subsequent transferring process for transferring the semiconductor devices 1 from the carrier 30 to another location. The transferring process of the semiconductor devices 1 will be described in the paragraphs below.

FIGS. 4B and 4C show a side view and a top view of a semiconductor device arrangement 2000 of FIG. 4A after removing one semiconductor device 1. Referring to FIG. 4C, in the top view, the upper surface of the carrier 30 can define a removal area 33 (as in dotted line), representing an exposed region on the carrier 30 after removing a semiconductor device 1. An indentation 34 is included in the removal area 33. The indentation 34 is a region, which is formed by pressing the conductive bump 2 to the adhesive structure 32, and the indentation 34 has a projected area in the top view. According to the experimental results, when the ratio of the projected area of the indentation 34 to the projected area of the semiconductor device 1 is less than 0.2, it is easier to pick up the semiconductor device 1 from the carrier 30 and move it to another location.

FIGS. 4D and 4E respectively show semiconductor device arrangements 3000 and 3001 in accordance with other embodiments of the present disclosure. FIG. 4D shows a semiconductor device arrangement 3000, and the semiconductor device arrangement 3000 includes a plurality of semiconductor devices 1 and a carrier 30. The carrier 30 includes a carrier plate 31 and an adhesive structure 32. The plurality of semiconductor devices 1 is disposed on the carrier 30 in a way that the conductive bumps 2 facing the carrier 30. The conductive bumps 2 and the electrodes 3 are completely embedded in the adhesive structure 32 and are completely wrapped by the adhesive structure 32. The adhesive structure 32 covers the lower surface of the semiconductor device 1 which is not covered by the electrode 3. By being temporarily fixed onto the adhesive structure 32, the positions of the semiconductor devices 1 on the carrier 30 can be maintained and are not easy to be changed during the subsequent processes. FIG. 4E shows another semiconductor device arrangement 3001. The semiconductor device arrangement 3001 includes a plurality of semiconductor devices 1 and a carrier 30. The carrier 30 includes a carrier plate 31 and a plurality of sub-adhesive structures 32″ separated from each other, and the horizontal position and width of a sub-adhesive structure 32″ are corresponded to a semiconductor device 1. As shown in FIG. 4E, an aisle 35 with a width greater than 0 is between two adjacent sub-adhesive structures 32″. The plurality of semiconductor devices 1 is disposed on the carrier 30 in such a way that the conductive bumps 2 facing the carrier 30. The conductive bumps 2 and the electrodes 3 are completely embedded in the sub-adhesive structure 32″ and are completely wrapped by the sub-adhesive structure 32″. The sub-adhesive structure 32″ covers the lower surface of the semiconductor device 1 which is not covered by the electrode 3.

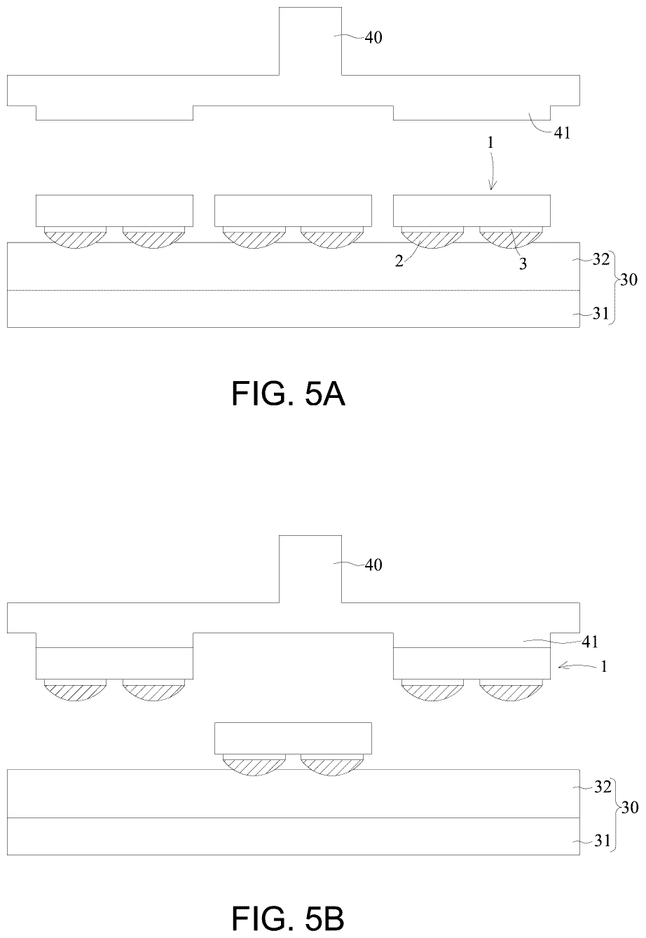

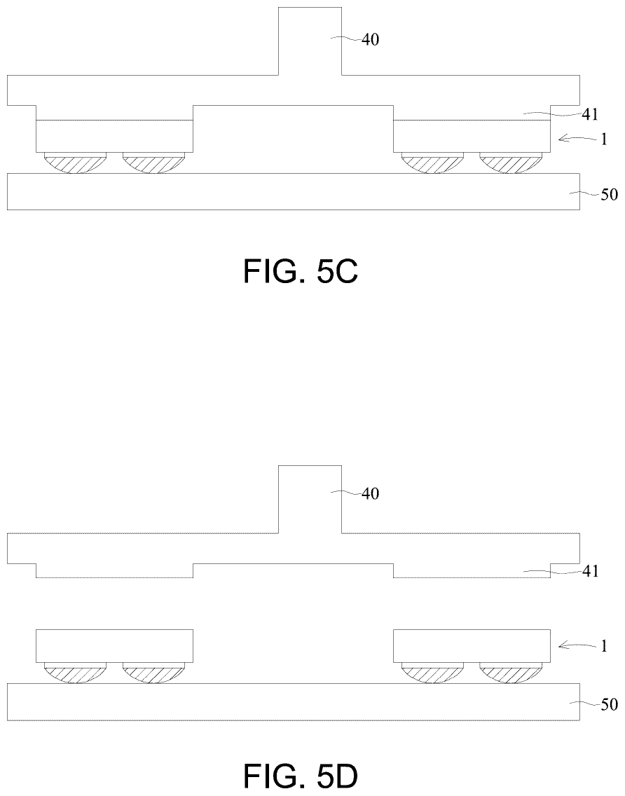

FIGS. 5A-5D show a procedure for transferring the semiconductor device 1 by a transferring structure 40. As shown in FIG. 5A, a plurality of semiconductor devices 1 is arranged in an array on the carrier 30. The plurality of semiconductor devices 1 is in contact with the adhesive structure 32 of the carrier 30 by portions of the surfaces of the conductive bumps 2 so the plurality of semiconductor device 1 can be temporarily fixed onto the carrier 30. A transferring structure 40 is provided to transfer the semiconductor device 1 from the carrier 30 to another location. The transferring structure 40 has a plurality of grabbing portions 41, and each of the grabbing portions 41 is corresponded to the position of the semiconductor device 1 which is ready to be picked up. As shown in FIG. 5B, the transferring structure 40 moves close to the plurality of semiconductor devices 1. After the grabbing portions 41 contacts some of the plurality of semiconductor devices 1, the transferring structure 40 moves upward so that the semiconductor devices 1 grabbed by the grabbing portions 41 leave the carrier 30. The adhesion between the grabbing portion 41 and the semiconductor device 1 is greater than the adhesion between the semiconductor device 1 and the carrier 30. The semiconductor devices 1, which are not contacted by the grabbing portions 41, stay on the carrier 30.

As shown in FIG. 5C, the transferring structure 40 moves to a position above a predetermined place of the target substrate 50 together with the semiconductor devices 1 temporarily fixed on the grabbing portions 41. At this predetermined place, the semiconductor devices 1 may directly or indirectly contact the target substrate 50, and eventually be placed or fixed on the target substrate 50. As shown in FIG. 5D, the semiconductor devices 1 leave the transferring structure 40 and stay on the target substrate 50, while the transferring structure 40 may move to the same or a different carrier 30 to grab other semiconductor devices 1. The transferred semiconductor devices 1 are disposed on the substrate 50 in such a way that the conductive bumps 2 face the target substrate 50. The target substrate 50 may be a circuit board of a display, a thin-film transistor (TFT) substrate, a substrate having a redistribution layer (RDL), or a sub-mount substrate of a package. In another embodiment, the target substrate 50 may be a temporary carrier similar to the carrier 30. In FIGS. 5A-5D, the connection mode of the semiconductor device 1 and the carrier 30 is not limited to the form shown in FIG. 4A, and may be the forms shown in FIGS. 4D and 4E.

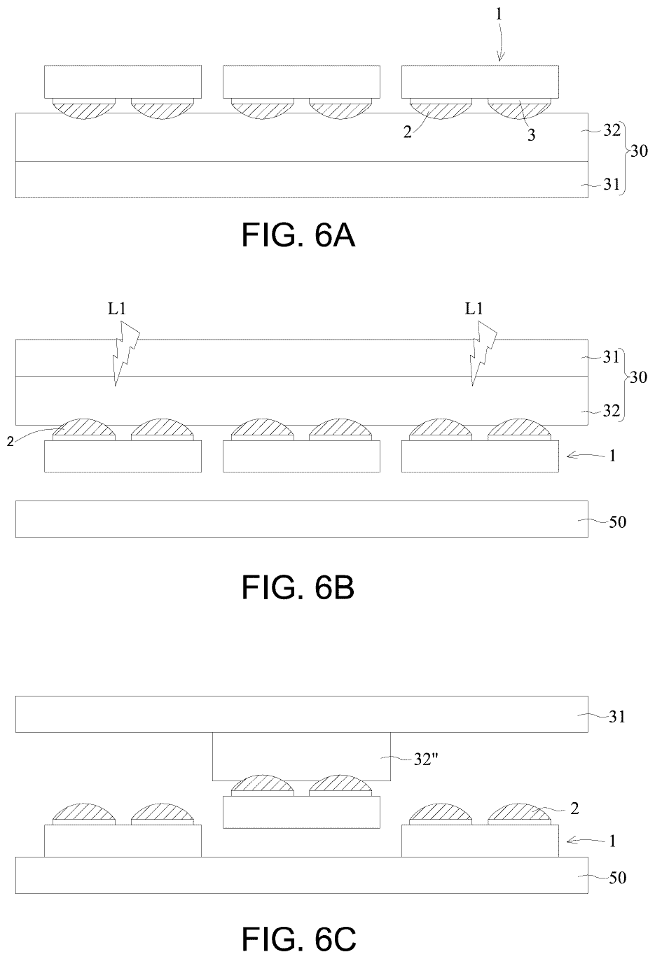

FIGS. 6A-6C are schematic views of a procedure for transferring the semiconductor device 1 in accordance with another embodiment of the present disclosure. FIG. 6A shows a plurality of semiconductor devices 1 disposed in an array on the carrier 30. Each semiconductor device 1 is in contact with the adhesive structure 32 of the carrier 30 by a portion of the surfaces of the conductive bumps 2 so the plurality of semiconductor devices 1 can be temporarily fixed onto the carrier 30. Then, the structure of FIG. 6A is flipped over or the target substrate 50 is moved, and such that the plurality of semiconductor devices 1 can be located between the carrier 30 and the target substrate 50 wherein the plurality of semiconductor devices 1 does not contact the target substrate 50. For example, as shown in FIG. 6B, the semiconductor device 1 is suspended over the target substrate 50. A laser energy L1 is provided to irradiate a specific place of the adhesive structure 32 from the side of the carrier plate 31, wherein the specific place corresponds to one of the semiconductor devices 1 which is ready to be transferred. The laser energy L1 may be a single-shot laser or a multi-shots laser. In an embodiment, one of the semiconductor devices 1 or a specific position of the adhesive structure 32 may be irradiated by one or more shots of laser during one irradiation process. In another embodiment, multiple places of the semiconductor devices 1 or of the adhesive structures 32 may be irradiated by one or more shots of laser, respectively, during one irradiation process. As shown in FIG. 6C, the adhesive structure 32 irradiated by the laser energy L1 may reduce the adhesion between the semiconductor device 1 and the adhesive structure 32, or cause the downward movement force of the semiconductor device 1 to be greater than the adhesion of the adhesive structure 32 to the semiconductor device 1, so that the semiconductor device 1 drops to the target substrate 50 from the carrier 30. The transferred semiconductor devices 1 are disposed on the target substrate 50 with the conductive bumps 2 being away from the substrate 50. In another embodiment, in the step of FIG. 6B, the semiconductor devices 1 may contact the target substrate 50 first, and then, be irradiated by the laser energy L1, so that the semiconductor devices 1 may align to the target substrate 50 more precisely. After the step of FIG. 6C, a removal step may be optionally applied to the semiconductor devices 1 to remove the remaining sub-adhesive structure 32″ on the semiconductor devices 1. The removal step may include a dry etch or a wet etch, and the dry etch may be an oxygen plasma etching process. In FIGS. 6A-6C, the connection mode of the semiconductor devices 1 and the carrier 30 is not limited to the form shown in FIG. 4A, and may also be the form shown in FIGS. 4D and 4E.

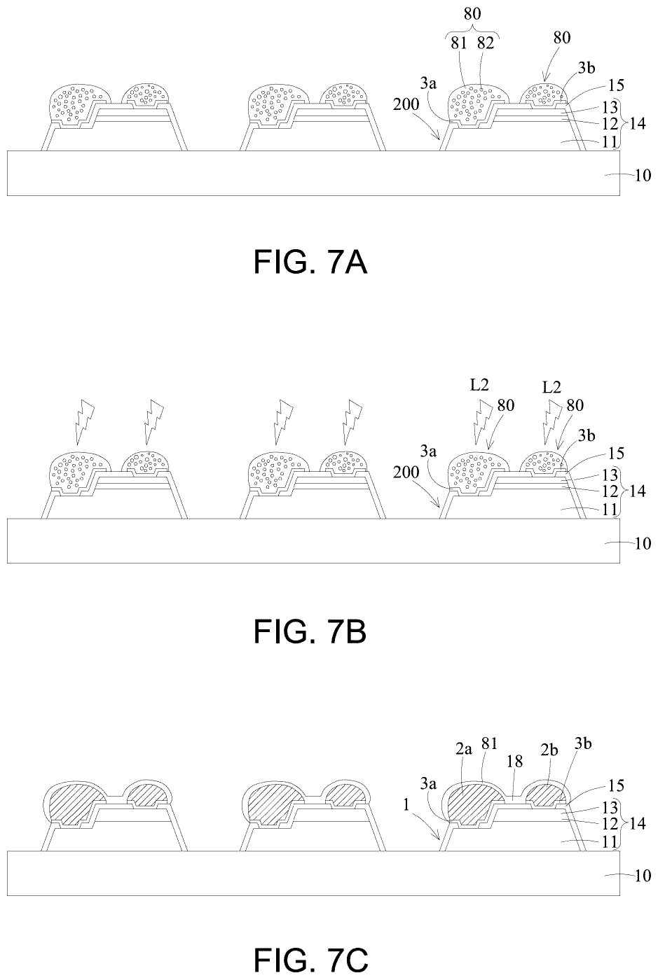

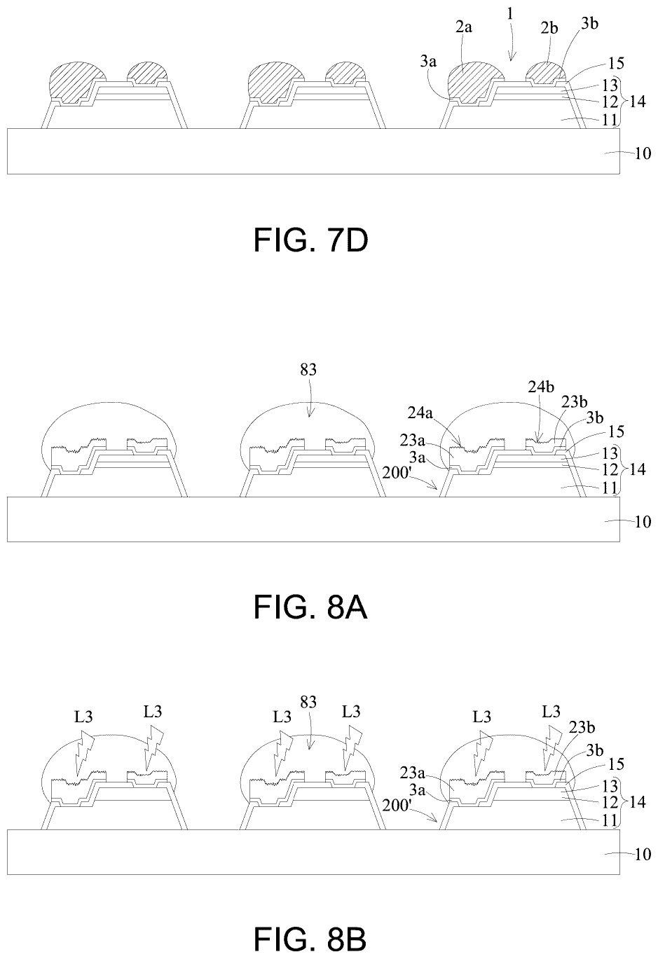

FIGS. 7A-7D are schematic views of a procedure for forming a semiconductor device 1 in accordance with an embodiment of the present disclosure. As shown in FIG. 7A, a plurality of semiconductor units 200 is disposed on a substrate 10. The semiconductor unit 200 includes a semiconductor stack 14, a protective layer 15, a first electrode 3a, and a second electrode 3b. The plurality of semiconductor units 200 is disposed on the substrate 10 with the first electrodes 3a and the second electrodes 3b being away from the substrate 10. The first electrode 3a and the second electrode 3b have recesses respectively. For the structures of the first electrode 3a and the second electrode 3b, references can be made to the aforementioned relevant paragraphs. Then, for each of the plurality of semiconductor units 200, two lumps of glue material 80 separated from each other are formed over the first electrode 3a and the second electrode 3b, respectively. The glue material 80 includes resin 81 and a plurality of conductive particles 82 distributed in the resin 81. In an embodiment, the glue material 80 may be formed by printing, coating, spraying, or dispensing. The printing may include aerosol jet printing or ink-jet printing. The material of the resin 81 includes thermosetting plastics and a soldering flux. The thermosetting plastics may be epoxy, silicone, polymethylmethacrylate (PMMA), or episulfide. The melting point of the conductive particle 82 is lower than the solid point of the resin 81. In an embodiment, the material of the conductive particle 82 may be gold, silver, or copper. In another embodiment, the material of the conductive particle 82 may be a low melting point metal or a low liquidus melting point alloy. In an embodiment, the melting point of the low melting point metal or the liquidus temperature of the low liquidus melting point alloy is lower than 210° C. In another embodiment, the melting point of the low melting point metal or the liquidus temperature of the low liquidus melting point alloy is lower than 170° C. The material of the low liquidus melting point alloy may be a tin alloy, such as a tin-indium alloy and tin-bismuth alloy.

As shown in FIG. 7B, a laser energy L2 is used to irradiate the glue material 80 or neighboring regions thereof to heat the glue material 80. The laser energy L2 may include UV laser beam, visible light laser beam, or IR laser beam. In an embodiment, the laser energy L2 is an IR pulse mode laser beam with wavelength of 750-2000 nm, spot size of 0.004-0.002 cm², beam diameter of 100-500 μm, pulse width (duration) of less than 20 ms, frequency of 500-4000 Hz, duty cycle of 1%-10%, laser power of 100 W, and laser energy of 595-850 J/cm². As shown in FIG. 7C, during the heating process, the conductive particles 82 gather on the first electrode 3a and the second electrode 3b to form the first conductive bump 2a and the second conductive bump 2b, wherein the first conductive bump 2a and the second conductive bump 2b are convex and have arc outer surfaces. A semiconductor unit 200 with the first conductive bump 2a and the second conductive bump 2b here is called a semiconductor device 1. In one embodiment, a portion of the resin 81 moves over the first conductive bump 2a, second conductive bump 2b, and the region 18 between the first electrode 3a and the second electrode 3b. After the heating process, the first conductive bump 2a and the second conductive bump 2b are cured, and the resin 81 covering the first conductive bump 2a and the second conductive bump 2b is also heated but not completely cured, so the resin 81 is in a liquid or semi-liquid state. Then, as shown in FIG. 7D, a cleaning step is performed to remove the uncured resin 81 so that the first conductive bump 2a and the second conductive bump 2b are exposed to the external environment for contacting the carrier plate in subsequent transferring process. The cleaning process may be performed with a solvent, and the solvent may include N-methylpyrrolidinone (NMP), methyl ethyl ketone (MEK), acetone (ACE), or isopropyl alcohol.

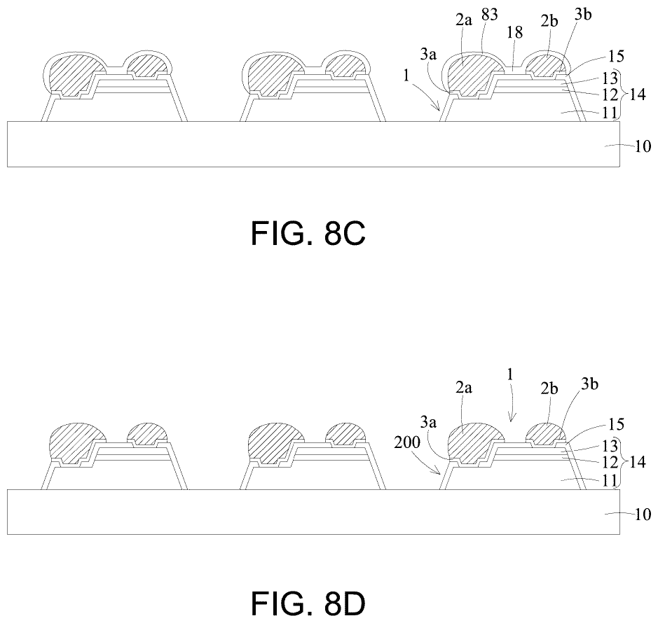

FIGS. 8A-8D are schematic views of a procedure for forming the semiconductor device 1 in accordance with another embodiment of the present disclosure. As shown in FIG. 8A, a plurality of semiconductor units 200′ is disposed over a substrate 10. The semiconductor unit 200′ includes a semiconductor stack 14, a protective layer 15, a first electrode 3a, and a second electrode 3b. The plurality of semiconductor units 200′ is disposed over the substrate 10 with the first electrode 3a and the second electrode 3b being away from the substrate 10. The first electrode 3a and the second electrode 3b have recesses respectively. For the structures of the first electrode 3a and the second electrode 3b, references can be made to the aforementioned relevant paragraphs. A first bonding pad 23a and a second bonding pad 23b are formed respectively on the first electrode 3a and the second electrode 3b by using a method of electroplating, chemical plating, or evaporation deposition. The upper surface 24a of the first bonding pad 23a and the upper surface 24b of the second bonding pad 23b are substantially conformal with the upper surface of the first electrode 3a and the second electrode 3b (i.e., the profiles of the both are similar). A single lump of the glue materials 83 is formed over the semiconductor unit 200′, first bonding pad 23a, and the second bonding pad 23b of each of the plurality of semiconductor units 200′. The glue material 83 only includes resin in this example. In another embodiment, the glue material 83 includes resin and lower concentration conductive particles (compared to the conductive particles of FIG. 7A). In an embodiment, the forming of the glue material 80 may be printing, coating, spraying, or dispensing. The printing may include aerosol jet printing or ink-jet printing. For the material of the first bonding pad 23a and the second bonding pad 23b, references can be made to the aforementioned relevant paragraphs of the conductive bump 2a, 2b. For the material of the resin, reference can be made to the aforementioned relevant paragraphs.

As shown in FIG. 8B, the first bonding pad 23a and the second bonding pad 23b or neighboring regions thereof are irradiated with a laser energy L3 to heat the glue materials 83, first bonding pad 23a, and the second bonding pad 23b. The laser energy L3 may include UV laser beam, visible light laser beam, or IR laser beam. In an embodiment, the laser energy L3 is IR laser beam with the wavelength of 750-2000 nm. As shown in FIG. 8C, during the heating process, the first bonding pad 23a and the second bonding pad 23b are heated to melt in the glue material 83 and gather on the first electrode 3a and the second electrode 3b (if the resin includes conductive particles, some or all of the heated conductive particles may also move toward the first electrode 3a and the second electrode 3b) to form a first conductive bump 2a and the second conductive bump 2b, wherein the first conductive bump 2a and the second conductive bump 2b are convex and have arc outer surfaces. A semiconductor unit 200′ with the first conductive bump 2a and the second conductive bump 2b here is called a semiconductor device 1. A portion of the glue material 83 moves over the first conductive bump 2a, the second conductive bump 2b, and the region 18 between the first electrode 3a and the second electrode 3b. After the heating process, the first conductive bump 2a and the second conductive bump 2b are cured, and the glue material 83 (or resin) covering thereon is heated but not completely cured, so the resin 81 is in a liquid or semi-liquid state. Then, as shown in FIG. 8D, a cleaning process is performed to remove the uncured glue material 83 (or resin) so that the first conductive bump 2a and the second conductive bump 2b are exposed to external environment for contacting the carrier plate in subsequent transferring process. For the cleaning process, reference can be made to the aforementioned relevant paragraphs of FIG. 7D.

In another embodiment, during the cleaning process of FIGS. 7D and 8D, if the glue material between the conductive bumps 2a and 2b is not cleaned completely and remained on the semiconductor 1, the maximum horizontal height of the remaining glue material is better not higher than the conductive bumps 2a and 2b for preventing from affecting the subsequent transfer and die-bonding process.

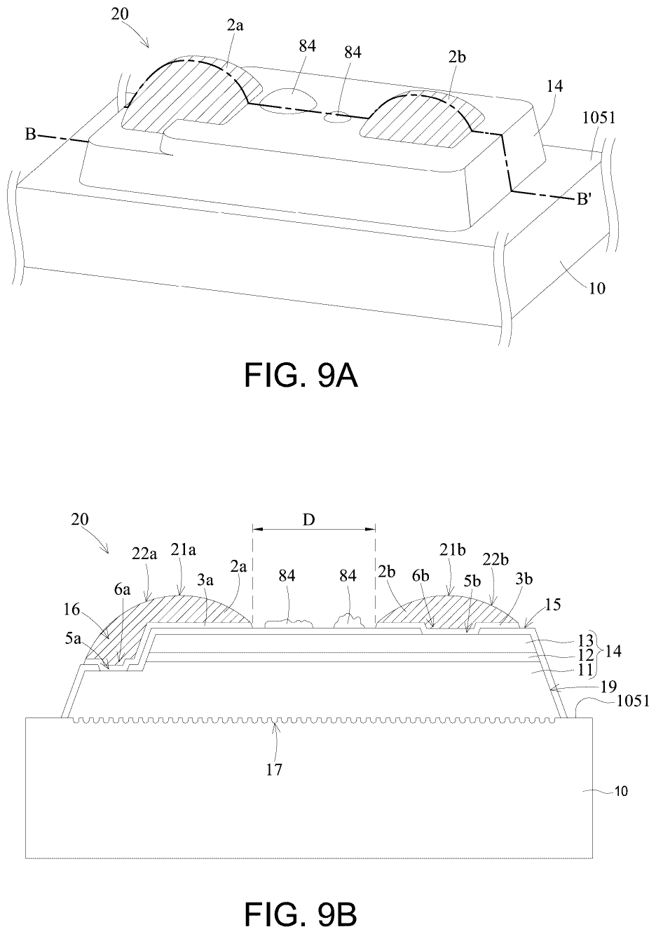

FIG. 9A is a three-dimensional view of a semiconductor device 20 in accordance with another embodiment of the present disclosure. FIG. 9B is a cross-sectional view taken along the line B-B′ of the semiconductor device 20 of FIG. 9A. Referring to FIG. 9A, the upper side of the semiconductor device 20 has a first conductive bump 2a and a second conductive bump 2b separated from each other. Between the first conductive bump 2a and the second conductive bump 2b, at least one lump of remaining glue material 84 is covered on the semiconductor device 20. In the top view, two lumps of remaining glue material 84 have irregular shapes and different areas. Referring to FIG. 9B, the semiconductor device 20 has a semiconductor stack 14, a protective layer 15, a first electrode 3a, a second electrode 3b, a first conductive bump 2a, and a second conductive bump 2b. The outermost side 19 of the semiconductor stack 14 is an inclined plane that is not perpendicular to the upper surface 1051 of the substrate 10. The semiconductor stack 14 includes a first semiconductor layer 11, an active layer 12, and a second semiconductor layer 13. The remaining glue material 84 is on the protective layer 15 between the first conductive bump 2a and the second conductive bump 2b. The uppermost surface of the remaining glue material 84 is not higher than the maximum horizontal height of the first conductive bump 2a and the second conductive bump 2b. Since the height of the remaining glue material 84 is not beyond that of the conductive bump 2a and 2b, the subsequent transferring and die-bonding process may not be affected.

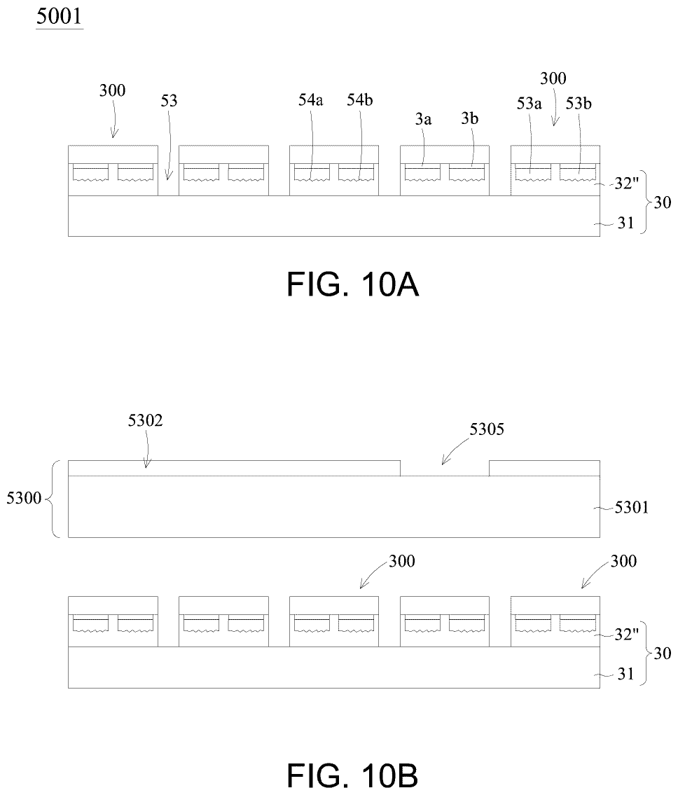

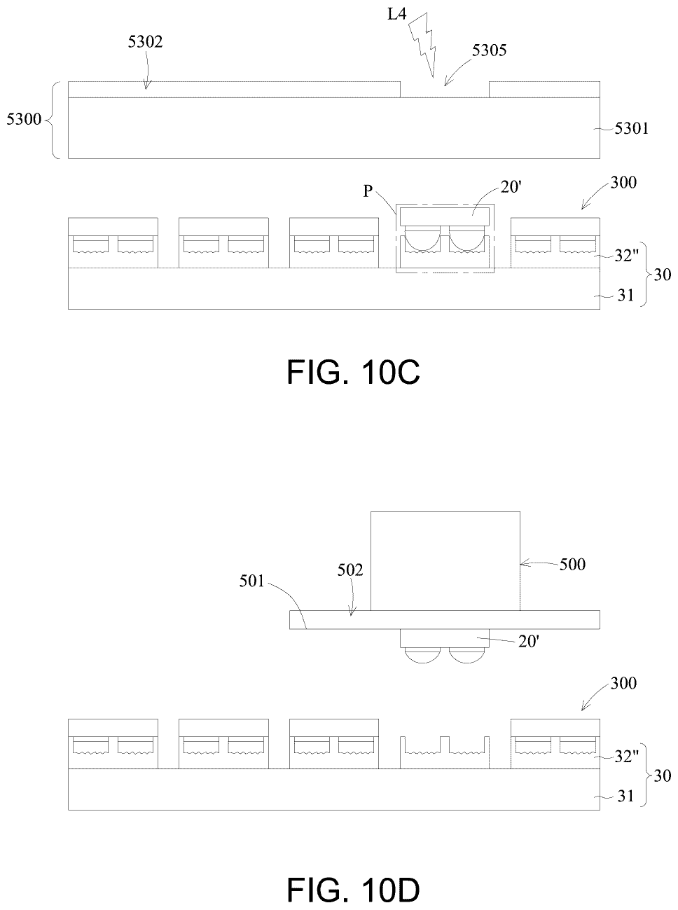

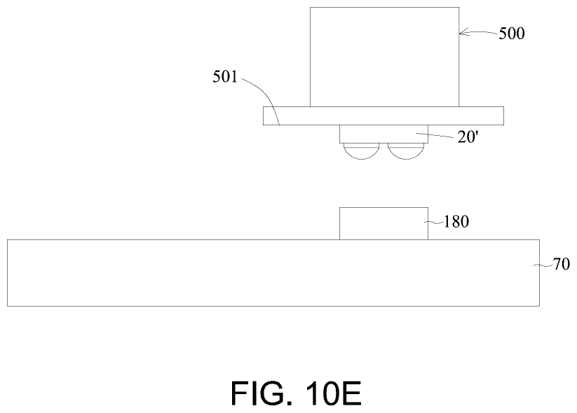

FIGS. 10A-10E are schematic views of a procedure for transferring the semiconductor device 20′ in accordance with another embodiment of the present disclosure. The structure of the semiconductor device 20′ can refer to the figures and paragraphs related to the semiconductor devices 1, 1′, and 20, and the structure of the semiconductor device arrangement 5001 can refer to FIG. 4E and the paragraphs related to the semiconductor device arrangement 3001. Wherein the semiconductor device arrangement 5001 includes a plurality of semiconductor units 300 arranged on the carrier 30 in the form of flip. The first bonding pad 53a and the second bonding pad 53b are respectively arranged below the first electrode 3a the second electrode 3b of the semiconductor unit 300.

In FIG. 10A, a plurality of semiconductor units 300 is disposed on the carrier 30 in a way that the electrodes 3a and 3b (bonding pads 53a and 53b) facing the carrier 30. The carrier 30 includes a carrier plate 31 with an upper surface and a plurality of sub-adhesive structures 32″ separated from each other located on the upper surface thereof, and one sub-adhesive structure 32″ is located under one semiconductor unit 300. The horizontal position and width of a sub-adhesive structure 32″ are corresponded to a semiconductor unit 300. An aisle 53 with a width greater than 0 is between two adjacent sub-adhesive structures 32″. The plurality of semiconductor units 300 is disposed on the carrier 30 in such a way that the bonding pads 53a and 53b are facing and embedded in the sub-adhesive structure 32″. The carrier 30 has a roughly square or round shape, and the material can be referred to the aforementioned paragraphs related to the substrate 10. In this step, the first bonding pad 53a and the second bonding pad 53b are located on electrodes 3a and 3b respectively, and the outer surfaces 54a and 54b are roughly conformal to the upper surfaces of the first electrode 3a and the second electrode 3b, that is, the contours of the two are similar. In one embodiment, the outer surface of the sub-adhesive structure 32″ is not coplanar with the outermost side of the semiconductor unit 300 and may be retracted or protruded relative to the outermost side of the semiconductor unit 300.

Then, as shown in FIG. 10B, a mask 5300 is arranged above the corresponding position of the semiconductor device arrangement 5001. The mask 5300 includes a translucent substrate 5301 (e.g., glass, quartz, sapphire) and a light-shielding metal layer 5302 (e.g., gold, chromium, tungsten) located on it. The light-shading metal layer 5302 has an opening 5305, and the size of the opening corresponds to a semiconductor unit 300 below or an array region containing a plurality of semiconductor units 300 (not shown), which can be an array of m′×n′ semiconductor units 300, wherein m′ and n′ are positive integers, and m′ and n′ are not 1 at the same time. In this embodiment, since the laser energy L4 is irradiated to the semiconductor unit 300 through the opposite side of the substrate 31, a material that the laser energy L4 can penetrate is selected as the substrate 31.

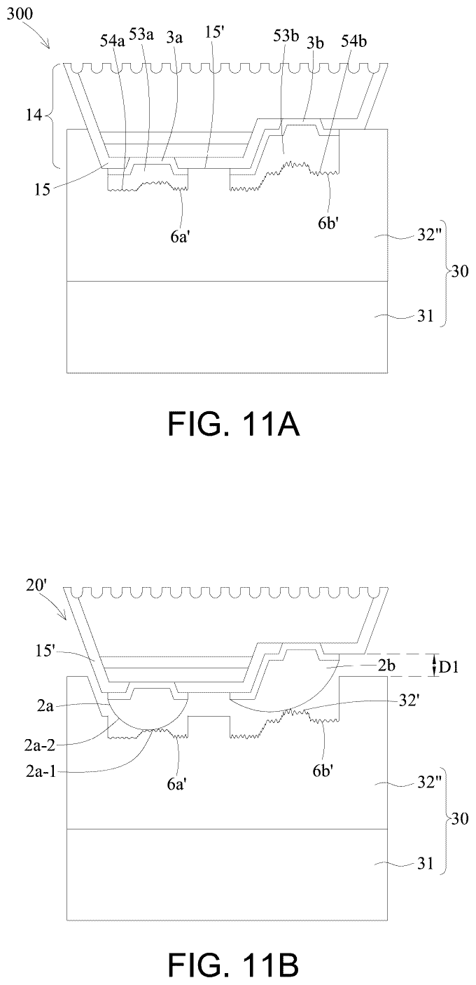

Then, as shown in FIG. 10C, a laser energy L4 from the top of the mask 5300 is passing through the position of the opening 5305 to irradiate one or a plurality of semiconductor units 300 below. The semiconductor unit(s) 300 irradiated by the laser energy L4 is formed as semiconductor device(s) 20′. More specifically, the laser energy L4 is irradiated through the opening 5305 towards the first bonding pad 53a and the second bonding pad 53b of the semiconductor unit 300 or the neighboring regions thereof, and the laser energy L4 may be a single-shot laser or a multi-shots laser. In other words, in one embodiment, the semiconductor unit(s) 300 may be irradiated with one-laser shot or multiple-laser shots during one irradiation process, and the first bonding pad 53a and the second bonding pad 53b irradiated by the laser energy L4 will be heated and gathered on the first electrode 3a and the second electrode 3b, forming the first conductive bump 2a and the second conductive bump 2b with the aforementioned convex arc outer surfaces. In this step, the structure with conductive bumps 2a, 2b is called a semiconductor device 20′. The contact area between the conductive bumps 2a and 2b of the semiconductor device 20′ and the underlying sub-adhesive structure 32″ is less than that of the bonding pads 53a and 53b of the semiconductor unit 300. Therefore, the semiconductor device 20′ is easier to be picked up in the semiconductor device arrangement 5001 than the semiconductor device 300 is. A more detailed mechanism will be described in the enlarged views of the following FIGS. 11A-11B.

Then, as shown in FIG. 10D, a transferring structure 500 is provided to move the semiconductor device 20′ from the carrier 30 to another place. In this embodiment, instead of using a protruding grabbing surface, the transferring structure 500 is a whole piece of an adhesive layer 502 (e.g., polydimethylsiloxan (PDMS) or adhesive tape with adhesive force), and the adhesive layer 502 has a grabbing surface 501 whose size is several times larger than the semiconductor device(s) to be picked-up. The transferring structure) moves close to the semiconductor unit(s) 300 and the semiconductor device(s) 20′, and after the grabbing surface 501 contacts with the semiconductor unit(s) 300 and the semiconductor device(s) 20′, it moves upwards so that the semiconductor device(s) 20′ adhered to the grabbing surface 501 and leaving the carrier 30 (sub-adhesive structure 32″), while the semiconductor unit 300 is not picked-up. At this time, the adhesion between the grabbing surface 501 and the semiconductor unit 300 is smaller than the adhesion between the semiconductor unit 300 and the sub-adhesive structure 32″. However, the adhesion between the grabbing surface 501 and the semiconductor device 20′ is greater than the adhesion between the semiconductor device 20′ and the sub-adhesive structure 32″. Therefore, after the transferring structure 500 leaves the sub-adhesive structure 32″ upwardly, the semiconductor unit 300 below the transferring structure 500 can still remain on the carrier 30, and the semiconductor device 20′ can be selectively picked-up and temporarily fixed on the grabbing surface 501.

Finally, the transferring structure 500 is moved to a predetermined position above a target substrate 70 together with the semiconductor device 20′ temporarily fixed on the grabbing surface 501. A surface circuit 180 can be selectively set at this predetermined position, and the transferred semiconductor device 20′ may contact or not contact the target substrate 70. As shown in FIG. 10E, while the semiconductor device 20′ is removed from the transferring structure 500 to the target substrate 70, it can be welded (electrically connected) to the surface circuit 180 below by directly heating and melting the conductive bumps 2a and 2b.

In one embodiment, according to the optoelectronic characteristic requirements for the semiconductor device 20′, the transferring structure 500 can be repeatedly moved to the same or different carriers 30 selectively grabbing the semiconductor devices 20′ which meet the requirements thereon to the target substrate 70. The selective transfer mode may transfer one semiconductor device 20′ at a time, or transfer a plurality of semiconductor devices 20′ in an array area at a time. The transferred semiconductor devices 20′ are electrically connected to the surface circuit 180 arranged on the target substrate 70 in the manner described above. The target substrate 70 may be a circuit board of a display, a thin-film transistor (TFT) substrate, a substrate having a redistribution layer (RDL), or a sub-mount substrate of a package. In another embodiment, the target substrate 70 may be a temporary carrier similar to the carrier 30 without surface circuit thereon.

FIGS. 11A-11B are enlarged views of the area P before and after being irradiated by the laser energy L4 in FIG. 10C. As shown in FIG. 11A, the semiconductor unit 300 includes a semiconductor stack 14, a protective layer 15, a first electrode 3a, and a second electrode 3b. The first bonding pad 53a and the second bonding pad 53b are respectively formed under the first electrode 3a and the second electrode 3b by electroplating, chemical plating, or evaporation. The outer surface 54a of the first bonding pad 53a and the outer surface 54b of the second bonding pad 53b are roughly conformal to the lower surfaces of the first electrode 3a and the second electrode 3b, that is, the contours of the two are similar. In addition, each of the outer surfaces 54a, 54b has a concave portion corresponding to each of the upper electrodes 3a, 3b, a rougher texture (relative to the lower surfaces of electrodes 3a, 3b), or both. At this step, the first bonding pad 53a, the second bonding pad 53b, and the electrodes 3a and 3b are embedded in the sub-adhesive structure 32″ and completely covered by the sub-adhesive structure 32″. The sub-adhesive structure 32″ is in direct contact with the outer surface 15′ of the semiconductor unit 300 that is not covered by electrodes 3a and 3b. As shown in the figure, the shapes of the concave regions 6a′ and 6b′ constituted by the sub-adhesive structure 32″ are corresponding to the first bonding pad 23a and the second bonding pad 23b.

As shown in FIG. 11B, after irradiated by the laser energy L4, the first bonding pad 53a and the second bonding pad 53b are heated and melted in the sub-adhesive structure 32″, and gathering under the first electrode 3a and the second electrode 3b to form a convex first conductive bump 2a and a convex second conductive bump 2b with arc outer surfaces. The semiconductor unit 300 with a first conductive bump 2a and a second conductive bump 2b is called a semiconductor device 20′. In more detail, since the first electrode 3a and the second electrode 3b are made of metal, when heated and melted, the first bonding pad 53a and the second bonding pad 53b, which are also made of metal, can aggregate inwardly based on the upper electrodes 3a and 3b to form conductive bumps 2a and 2b in order to have lower surface area and lower surface energy, respectively. Conductive bumps 2a and 2b can push the sub-adhesive structure 32″ and lift the semiconductor device 20′ upwardly from the sub-adhesive structure 32″. As shown in FIG. 11B, the contact area between the conductive bumps 2a and 2b and the sub-adhesive structure 32″ is smaller than that of the first bonding pad 53a and the second bonding pad 53b and the sub-adhesive structure 32″ shown in FIG. 11A, and the outer surface 15′ of the semiconductor device 20′ and the sub-adhesive structure 32″ can be separated by a distance D1. The first conductive bump 2a is located under the outer surface 15′ of the semiconductor device 20′, in the concave region 6a, and includes a first portion 2a-1 in direct contact with the concave portion 6a and a second portion 2a-2 not in direct contact with the concave portion 6a. As a result, the adhesion of the semiconductor device 20′ to the sub-adhesive structure 32″ becomes smaller than that of the semiconductor unit 300.

In one embodiment, the sub-adhesive structure 32″ is cured after being heated and is in contact with the outer surface 54a and 54b of the bonding pad 53a and 53b. Therefore, when the semiconductor device 20′ is removed, the inner contours of the corresponding bonding pads 53a and 53b are still retained in the concave regions 6a′ and 6b′. In another embodiment, the sub-adhesive structure 32″ produces some fluidity when it is heated and melted, therefore, after the semiconductor device 20′ is removed, the concave regions 6a′ and 6b′ become smoother and the roughness thereof decrease, and although the sub-adhesive structure 32″ undergoes some deformation, the roughness of the concave regions 6a′ and 6b′ is still larger than that of the outer surfaces of the conductive bumps 2a and 2b.

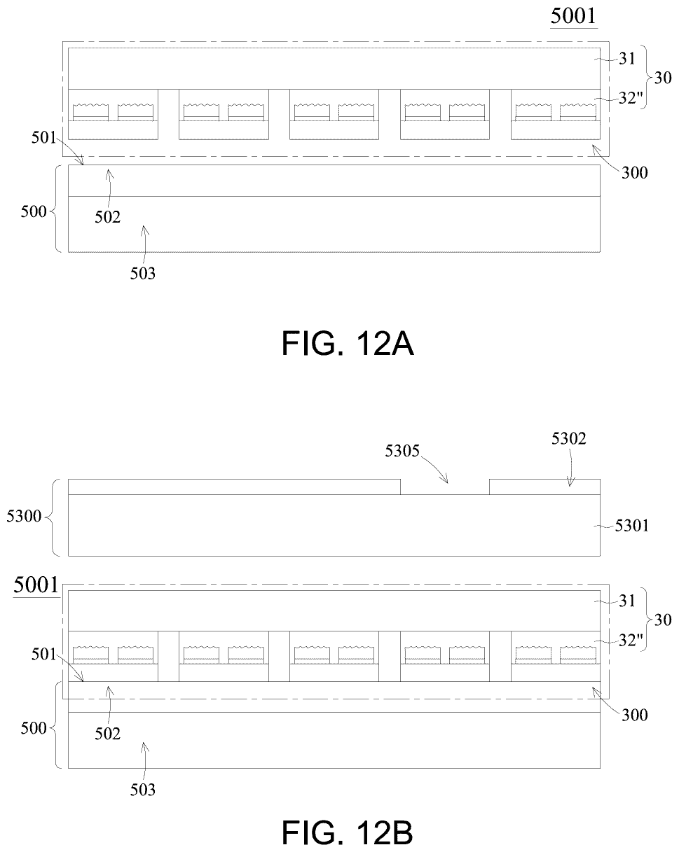

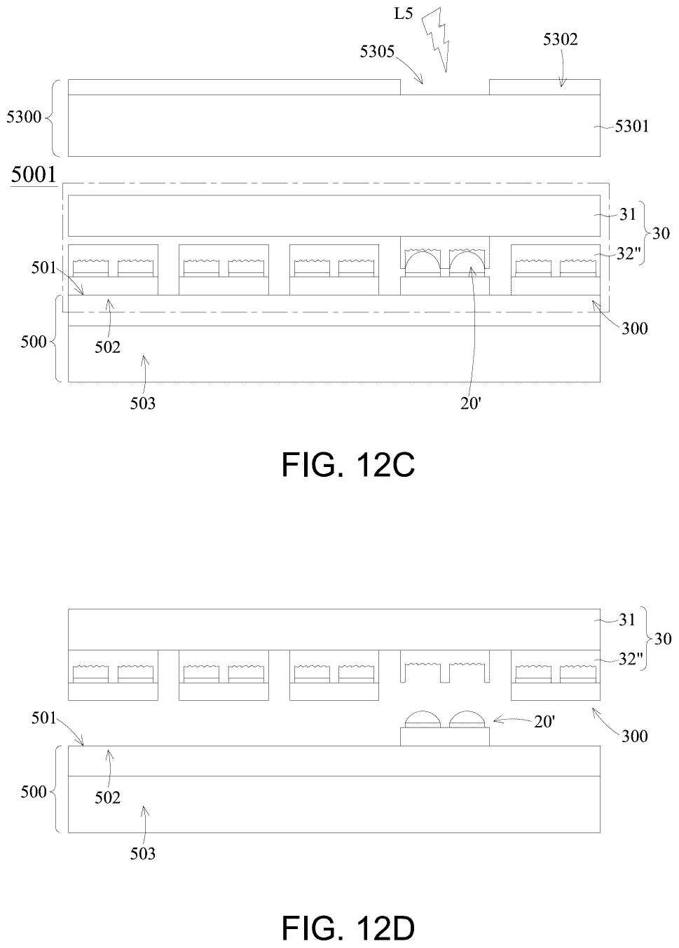

FIGS. 12A-12D are schematic views of a procedure for transferring the semiconductor device 20′ in accordance with another embodiment of the present disclosure. As shown in FIG. 12A, the semiconductor device arrangement 5001 includes a plurality of semiconductor units 300 facing toward and in contact with the adhesive transferring structure 500 with the backsides thereof. In this embodiment, the transferring structure 500 includes a supporting layer 503 and an adhesive layer 502 (e.g., polydimethylsiloxan (PDMS)). The adhesive layer 502 includes a grabbing surface 501, and the semiconductor units 300 are in contact with the grabbing surface 501. The transferring structure 500 may optionally be subjected to a pressure toward the carrier 30 to ensure that the backsides of the semiconductor units 300 are contact to the grabbing surface 501.

Then, as shown in FIG. 12B, a mask 5300 is arranged above the semiconductor device arrangement 5001. The mask 5300 includes a translucent substrate 5301 (e.g., glass, quartz, sapphire) and a light-shielding metal layer 5302 (e.g., gold, chromium, tungsten) located on it. The light-shading metal layer 5302 has an opening 5305, and the size of the opening corresponds to a semiconductor unit 300 below or an array region containing a plurality of semiconductor units 300

As shown in FIG. 12C, a laser energy L5 is provided from the top of the mask 5300 through the opening 5305 to one or a plurality of semiconductor units 300. The semiconductor units 300 irradiated by the laser energy L4 become semiconductor devices 20′.

As shown in FIG. 12D, when the carrier 30 is separated from the transferring structure 500, the semiconductor device 20′ can be separated from the sub-adhesive structure 32″ and transferred to the grabbing surface 501. Subsequently, referring to FIG. 10E, the semiconductor device 20′ is arranged to a predetermined position of the target substrate 70 by the transferring structure 500.

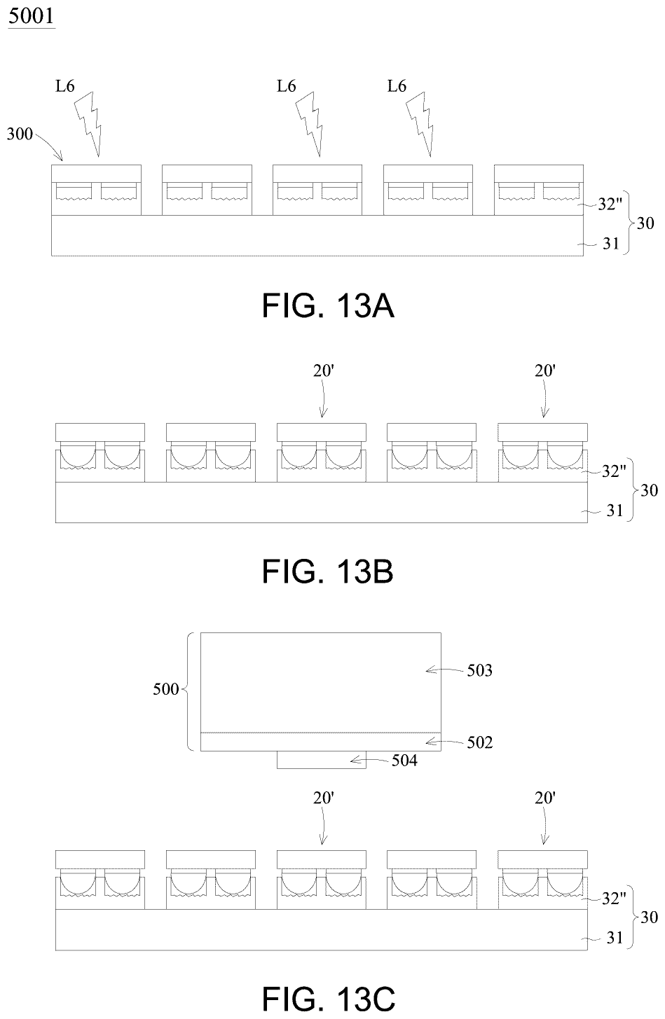

FIGS. 13A-13D are schematic views of a procedure for transferring the semiconductor device 20′ in accordance with another embodiment of the present disclosure. In this embodiment, a mask is not required. As shown in FIG. 13A, a laser energy L6 is applied directly to the surface of all semiconductor units 300 by scanning.

As shown in FIG. 13B, after applying the laser energy L6, all semiconductor units 300 are formed into semiconductor devices 20′, so the adhesion between the semiconductor devices 20′ and carrier 30 (sub-adhesive structure 32″) becomes smaller than that between semiconductor units 300 and carrier 30 (sub-adhesive structure 32″). The structure and manufacturing methods of semiconductor units 300 and semiconductor devices 20′ may be referred to FIGS. 11A-11B and related paragraphs.

As shown in FIG. 13C, the transferring structure 500 with a protruding grabbing portion 504 is used to pick up a specific semiconductor device 20′ using an adhesive layer 502 with a protruding grabbing portion. In an embodiment, a grabbing portion 504 has a similar projected area with a semiconductor device 20′, and a grabbing portion 504 may pick a semiconductor device 20′ up at a time. After the transferring structure 500 is moved to a specific semiconductor device 20′ and the grabbing portion 504 is in contact with the semiconductor device 20′, the transferring structure 500 is moved upwards so that the semiconductor device 20′ is picked up by the grabbing portion 504 and leaves the carrier 30 (sub-adhesive structure 32″), and the semiconductor device 20′ that is not in contact with the grabbing portion 504 remains on the carrier 30 (sub-adhesive structure 32″). At this time, the adhesion between the grabbing portion 504 and the semiconductor device 20′ is greater than the adhesion between the semiconductor device 20′ and the carrier 30 (sub-adhesive structure 32″). Subsequently, as mentioned above, the semiconductor device 20′ is placed on a predetermined position of the target substrate (not shown) by the transferring structure 500.

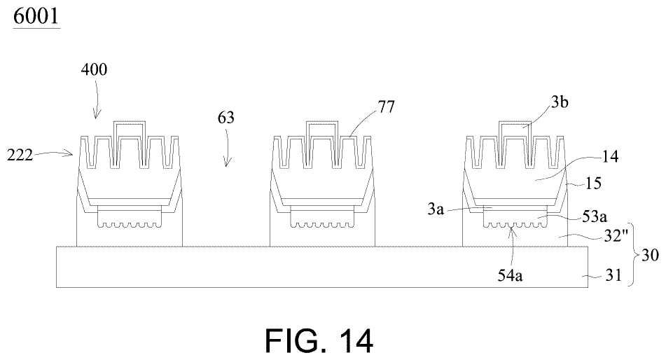

FIG. 14 shows a cross-sectional view of another semiconductor device arrangement 6001. As shown in FIG. 14, the semiconductor unit 400 is a vertical light-emitting diode chip. The semiconductor unit 400 includes a semiconductor stack 14, a protective layer 15, a first electrode 3a, and a second electrode 3b. The first bonding pad 53a is formed under the first electrode 3a by electroplating, chemical plating, or evaporation. The outer surface 54a of the first bonding pad 53a is roughly conformal with the lower surface of the first electrode 3a, that is, the contours of the two are similar. The first electrode 3a and the first bonding pad 53a are positioned below the semiconductor stack 14 and are embedded in the sub-adhesive structure 32″; The second electrode 3b is located above the semiconductor stack 14. In other words, the first electrode 3a (and the first bonding pad 53a) and the second electrode 3b are respectively located on opposite sides of the semiconductor stack 14. In addition, the upper surface of the semiconductor stack 14 can be selectively covered with a light-transmitting conductive layer 77 (e.g., indium-tin oxide) to increase the current diffusion effect on the surface of the semiconductor unit 400.

As shown in FIG. 14, a plurality of sub-adhesive structures 32″ is arranged on the carrier 30 and separated from each other, and a sub-adhesive structure 32″ is located below a semiconductor unit 222 and has a width substantially equal to that of a semiconductor unit 222. There is an aisle 63 between the adjacent sub-adhesive structures 32″ with a distance greater than 0. The method of transferring the semiconductor unit 222 in the semiconductor device arrangement 6001 may be referred to FIGS. 5A-5D, FIGS. 6A-6C, FIGS. 10A-10E, FIGS. 12A-12D, FIGS. 13A-13C, and related paragraphs. Wherein, when a laser energy is applied to the semiconductor unit 222, the adhesion between the semiconductor unit 222 and the carrier 30 (sub-adhesive structure 32″) is reduced by simply converting the first bonding pad 53a embedded in the sub-adhesive structure 32″ into an arc-shaped conductive bump (not shown).

It should be understood that many of the above embodiments in this disclosure can be combined or replaced with each other under appropriate circumstances, and are not limited to the specific embodiments described. For example, in the preceding embodiments, the semiconductor unit and semiconductor device may contain a growth substrate or no growth substrate.

Although some embodiments of the present disclosure and their advantages have been described in detail, various changes, substitutions and alterations may be made herein without departing from the spirit and scope of the disclosure as defined by the appended claims.

What is claimed is:

1. A semiconductor device arrangement, comprising:
a substrate, comprising an upper surface;
an adhesive structure, located on the upper surface and comprising a first concave region;
a first semiconductor device, comprising:
a lower surface, facing toward the adhesive structure; and
a conductive bump, located under the lower surface and in the first concave region, and comprising a first portion and a second portion;
wherein the lower surface does not contact the adhesive structure;
wherein the first portion contacts the first concave region, and the second portion does not contact the first concave region.

2. The semiconductor device arrangement according to claim 1, further comprising a second semiconductor device which comprises a bonding pad, and wherein the adhesive structure further comprises a second concave region, and in a cross-sectional view, the bonding pad has roughly the same contour as that of the second concave region.

3. The semiconductor device arrangement according to claim 2, wherein the bonding pad comprises a first outer surface, the conductive bump comprises a second outer surface, and the first outer surface comprises a concave portion or a texture rougher than that of the second outer surface.

4. The semiconductor device arrangement according to claim 2, wherein the adhesive structure comprises a first sub-adhesive structure and a second sub-adhesive structure separated from each other, the first semiconductor device is located on the first sub-adhesive structure, and the second semiconductor device is located on the second sub-adhesive structure.

5. The semiconductor device arrangement according to claim 1, wherein the first adhesive structure comprises a first maximum width, the first semiconductor device comprises a second maximum width, and the first maximum width is substantial the same as the second maximum width.

6. The semiconductor device arrangement according to claim 1, further comprising a plurality of particles discretely distributed within the conductive bump.

7. The semiconductor device arrangement according to claim 6, the semiconductor device further comprising an electrode under the lower surface, and wherein a material of the plurality of particles is the same as a material of the electrode, and is different from a material of the conductive bump.

8. The semiconductor device arrangement according to claim 6, wherein the plurality of particles comprises gold, platinum, or alloys thereof.

9. The semiconductor device arrangement according to claim 1, wherein the conductive bump is substantially a rectangle in a top view.

10. The semiconductor device arrangement according to claim 1, further comprising a glue material on the first semiconductor device and separated from the conductive bump.

11. The semiconductor device arrangement according to claim 9, wherein a height of the glue material is smaller than a height of the conductive bump.

12. A method of manufacturing a semiconductor device arrangement, comprising:
providing a substrate comprising an upper surface;
disposing an adhesive structure on the upper surface;
disposing a first semiconductor device and a second semiconductor device on the adhesive structure;
providing an energy to the first semiconductor device such that a contact area between the first semiconductor device and the adhesive structure is reduced;
providing a transferring structure to contact the first semiconductor device and the second semiconductor device simultaneously; and
removing the transferring structure to transfer the first semiconductor device to the transferring structure.

13. The method of manufacturing a semiconductor device arrangement according to claim 12, further comprising providing a mask with an opening, and providing the energy to the first semiconductor device by providing a laser energy to the first semiconductor device through the opening.

14. The method of manufacturing a semiconductor device arrangement according to claim 12, wherein the opening corresponds to the first semiconductor device or a region larger than two of the first semiconductor devices.

15. The method of manufacturing a semiconductor device arrangement according to claim 12, wherein the mask comprises a translucent substrate and a light-shielding layer located thereon.

16. The method of manufacturing a semiconductor device arrangement according to claim 12, wherein the first semiconductor device comprises a bonding pad, and a contour of the bonding pad is changed after the step of providing an energy to the first semiconductor device.

17. The method of manufacturing a semiconductor device arrangement according to claim 12, wherein the first semiconductor device comprises a lower surface, and the lower surface is separated from the adhesive structure after the step of providing an energy to the first semiconductor device.

18. The method of manufacturing a semiconductor device arrangement according to claim 12, further comprising a target substrate, and transferring the first semiconductor device from the transferring structure to the target substrate by removing the transferring structure.

19. The method of manufacturing a semiconductor device arrangement according to claim 18, wherein the target substrate comprises a circuit board of a display, a TFT substrate, a substrate having redistribution layer (RDL), or a sub-mount substrate.

20. The method of manufacturing a semiconductor device arrangement according to claim 12, further comprising a step of retaining the second semiconductor device on the substrate after removing the transferring structure to transfer the first semiconductor device to the transferring structure.
